(19) United States
(12) Patent Application Publication
(10) Pub. No.: US 2010/0019297 A1
(43) Pub. Date: Jan. 28, 2010

(54) Multi-Stacked Spin Transfer Torque Magnetic Random Access Memory and Method of Manufacturing the Same

(75) Inventor: Sang Min Hwang, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/265,389

(22) Filed: Nov. 5, 2008

(30) Foreign Application Priority Data
Jul. 25, 2008 (KR) 10-2008-0072823

(51) Int. Cl. H01L 21/8246; H01L 27/22

(52) U.S. Cl. 257/295; 438/3; 257/E27.005; 257/E21.665

(57) ABSTRACT

A spin transfer torque magnetic random access memory (STT-MRAM) device comprises adjacent magnetic tunneling junctions (MTJ), respectively, formed in different layers, thereby preventing interference between the MTJs and securing thermal stability.

### CROSS-REFERENCES TO RELATED APPLICATIONS

Priority is claimed to Korean patent application number 10-2008-0072823, filed on Jul. 25, 2008, which is incorporated by reference in its entirety.

### BACKGROUND OF THE INVENTION

The present invention generally relates to a spin transfer torque magnetic random access memory (STT-MRAM) device, and more specifically, to a multi-stacked STT-MRAM device that includes magnetic tunneling junctions (MTJ) of adjacent cells, respectively, formed in different layers, and a method of manufacturing the same.

Dynamic random access memory (DRAM) occupies the largest memory market. DRAM comprises a MOS transistor and a capacitor, which are paired, functioning as 1 bit. DRAM is a volatile memory that requires a periodic refresh operation in order not to lose data because the DRAM writes data by storing charges in the capacitor.

As an example of non-volatile memory, a NAND/NOR flash memory does not lose a stored signal even when a power source is off like hard disk. Particularly, the NAND flash memory has the highest integration of the common memories. This flash memory is light because it can be formed smaller than the hard disk, is resistant to physical impact, has a fast access speed, and has small power consumption. As a result NAND flash memory has been used as a storage medium for mobile products. However, the flash memory has a slower speed than that of the DRAM and has a high operating voltage.

The usage of the memory is various. As mentioned above, DRAM and flash memory are respectively adapted in different products because they have different characteristics. Recently, various attempts to develop a memory having advantages of these two memories have been made. For example, there are a phase change RAM (PCRAM), a magnetic RAM (MRAM), a polymer RAM (PoRAM), and a resistive RAM (ReRAM).

Of these memories, MRAM uses resistive change resulting from polarization change of magnetic substance as a digital signal, which is a successful memory in commercialization of the product of lower capacity. Moreover, MRAM using magnetism is not destroyed even resulting from radioactive exposure making it the stablest memory.

However, the conventional MRAM, which includes a digit line parallel to a word line, writes data using vector addition of the magnetic field generated when a current flows simultaneously in a bit line and the digit line. That is, the conventional MRAM is required to include a bit line and an additional digit line. As a result, the cell size becomes larger, and the cell efficiency is degraded in comparison with other memories. Also, while the conventional MRAM selects one cell to write data, unselected cells are exposed in the magnetic field, which is called a half-selection phenomenon. As a result, a disturbing phenomenon inverting neighboring cells occurs.

Recently, a STT-MRAM has been developed which does not require the digit line to facilitate miniaturization and prevents the disturbing phenomenon resulting from the half selection in a write mode. The STT-MRAM uses a spin transfer torque phenomenon. When the high density current having an aligned spin direction flows through the ferromagnet, if a magnetization direction of a ferromagnet is not identical with the spin direction of the current, the magnetization direction of a ferromagnet is transferred to the spin direction of the current.

FIG. 1 is a circuit diagram illustrating a general STT-MRAM.

A STT-MRAM may include a MTJ and a transistor connected between bit lines BL0, BL1 and source lines SL0˜SL3.

A transistor 12 connected between the source lines SL0˜SL3 and the MTJ is turned on depending on a voltage applied through word lines WL0˜WL3 when data are read/written, so that a current flows between the source lines SL0˜SL3 and the bit lines BL0, BL1. A dummy word line DWL is formed between the word lines WL0˜WL3. The dummy word line DWL may not be formed depending on a process of forming a source/drain.

The MTJ connected between the bit line BL and the source/drain region of the transistor includes two magnetic layers and a tunnel barrier between the magnetic layers. The bottom magnetic layer includes a pinned ferromagnetic layer whose magnetization direction is fixed. The top magnetic layer includes a free ferromagnetic layer whose magnetization direction is varied depending on a direction of a current applied to the MTJ.

The MTJ writes data “0” or “1” because its resistance value is changed depending on the current direction. That is, when a current flows from the source line SL to the bit line BL, a magnetization direction of the free ferromagnetic layer is switched in parallel with that of the pinned ferromagnetic layer, so that the data “0” is stored. On the other hand, when a current flows from the bit line BL to the source line SL, the magnetization direction of the free ferromagnetic layer is switched in anti-parallel with that of the pinned ferroelectric layer, so that the data “1” is stored.

The data stored in the MTJ are read by sensing a difference in the current amount flowing through the MTJ depending on a magnetization state of the MTJ.

FIG. 2 is a cross-sectional diagram illustrating the circuit of FIG. 1.

A gate electrode 4 is formed over a silicon substrate 1 having a device isolation film (FOX) 2 and an active region 3. A landing plug contact 5 is formed between the gate electrodes 4.

A source line contact 6 and a bottom electrode contact 8 are formed over the landing plug contact 5. The source line contact 6 connects a source line 7 to the landing plug contact 5. The bottom electrode contact 8 connects the MTJ to the landing plug contact 5. The MTJs are formed over the same surface.

However, a magnetic field interference phenomenon occurs between the adjacent MTJs when the chip size becomes smaller. That is, as a distance between the MTJs becomes smaller, the magnetization direction of the free ferromagnetic layer is switched by the interference of the same magnetic pole.

As a result, there is a limit in reduction of the cell size of the conventional STT-MRAM.

In the MTJ, the thermal stability is enhanced as the ratio of the width and length of the MTJ becomes larger. Also, there is a limit in increase of the size when the MTJs are formed over the same surface.

### BRIEF SUMMARY OF THE INVENTION

Various embodiments of the present invention are directed at improving a cell structure of a STT-MRAM to secure thermal stability of a MTJ and to minimize interference between adjacent MTJs, thereby improving operating characteristics of the STT-MRAM.

According to an embodiment of the present invention, a multi-stacked spin transfer torque magnetic random access memory (STT-MRAM) device may include: a first magnetic tunneling junction (MTJ) connected to a first source/drain region of a first cell; and a second MTJ connected to a first source/drain region of a second cell adjacent to the first cell. The first MTJ and the second MTJ are formed in different layers, respectively.

Preferably, the multi-stacked STT-MRAM further may include: a first source line connected to a second source/drain region of the first cell; and a second source line connected to a second source/drain region of the second cell.

In the multi-stacked STT-MRAM device, the first source line and the second source line may be formed in the same layer.

In the multi-stacked STT-MRAM device, he first cell and the second cell may be formed in different active regions, respectively.

Preferably, the multi-stacked STT-MRAM device further may include a common source line connected to a third source/drain region shared by the first cell and the second cell.

In the multi-stacked STT-MRAM device, the first MTJ and the second MTJ may be formed to have a square or rectangular shape.

In the multi-stacked STT-MRAM device, the first MTJ and the second MTJ, respectively, may have an ratio of the width and length of 1:1˜1:5.

In the multi-stacked STT-MRAM device, the first MTJ and the second MTJ may be formed to have a circular or oval shape.

In the multi-stacked STT-MRAM device, the first MTJ and the second MTJ, respectively, may have an ratio of the major axis and minor axis of 1:1˜1:5.

According to an embodiment of the present invention, a method of manufacturing a multi-stacked STT-MRAM device may include: forming a first gate electrode and a second gate electrode over a semiconductor substrate; forming a first source line connected to a first source/drain region adjacent to the first gate electrode and a second source line connected to a second source/drain region adjacent to the second gate electrode over the first and second gate electrodes; forming a first MTJ connected to a third source/drain region adjacent to the first gate electrode over the first and second source lines; and forming a second MTJ connected to a fourth source/drain region adjacent to the second gate electrode over the first MTJ.

Preferably, the forming-first-and-second-source-lines includes: forming a first interlayer insulating film over the first and second gate electrodes; selectively etching the first interlayer insulating film to form first and second source line contacts, respectively, connected to the first source/drain region and the second source/drain region; and forming and patterning a metal film over the first interlayer insulating film, the first source line contact and the second source line contact.

Preferably, the forming-a-first-MTJ includes: forming a second interlayer insulating film over the first source line, the second source line and the first interlayer insulating film; selectively etching the second interlayer insulating film and the first interlayer insulating film to form a first bottom electrode contact connected to the third source/drain region; sequentially forming a first pinned ferromagnetic layer, a first tunnel junction layer and a first free ferromagnetic layer over the second interlayer insulating film and the first bottom electrode contact; and patterning the first pinned ferromagnetic layer, the first tunnel junction layer and the first free ferromagnetic layer.

Preferably, the forming-a-second-MTJ includes: forming a third interlayer insulating film over the first MTJ and the second interlayer insulating film; selectively etching the third interlayer insulating film, the second interlayer insulating film and the first interlayer insulating film to form a second bottom electrode contact connected to the source source/drain region; sequentially forming a second pinned ferromagnetic layer, a second tunnel junction layer and a second free ferromagnetic layer over the third interlayer insulating film and the second bottom electrode contact; and patterning the second pinned ferromagnetic layer, the second tunnel junction layer and the second free ferromagnetic layer.

According to an embodiment of the present invention, a method of manufacturing a multi-stacked STT-MRAM device may include: forming a first gate electrode and a second gate electrode over a semiconductor substrate; forming a common source line connected to a first source/drain region adjacent in common to the first and second gate electrodes over the first and second gate electrodes; forming a first MTJ connected to a second source/drain region adjacent to the first gate electrode over the common source line; and forming a second MTJ connected to a third source/drain region adjacent to the second gate electrode over the first MTJ.

Preferably, the forming-a-common-source-line may include: forming a first interlayer insulating film over the first gate electrode and the second gate electrode; selectively etching the first interlayer insulating film to form a source line contact connected to the first source/drain region; and forming and patterning a metal film over the first interlayer insulating film and the source line contact.

Preferably, the forming-a-first-MTJ may include: forming a second interlayer insulating film over the common source line and the first interlayer insulating film; selectively etching the second interlayer insulating film and the first interlayer insulating film to form a first bottom electrode contact connected to the second source/drain region; sequentially forming a first pinned ferromagnetic layer, a first tunnel junction layer and a first free ferromagnetic layer over the second interlayer insulating film and the first bottom electrode contact; and patterning the first pinned ferromagnetic layer, the first tunnel junction layer and the first free ferromagnetic layer.

Preferably, the forming-a-second-MTJ may include: forming a third interlayer insulating film over the first MTJ and the second interlayer insulating film; selectively etching the third interlayer insulating film, the second interlayer insulating film and the first interlayer insulating film to form a second bottom electrode contact connected to the third source/drain region; sequentially forming a second pinned ferromagnetic layer, a second tunnel junction layer and a second free ferromagnetic layer over the third interlayer insulating film and the second bottom electrode contact; and patterning the second pinned ferromagnetic layer, the second tunnel junction layer and the second free ferromagnetic layer.

### BRIEF DESCRIPTION OF THE DRAWINGS

FIG. 1 is a circuit diagram illustrating a general STT-MRAM.

FIG. 2 is a cross-sectional diagram illustrating the circuit of FIG. 1.

FIG. 3 is a cross-sectional diagram illustrating a STT-MRAM according to an embodiment of the present invention.

FIGS. 4 to 8 are cross-sectional diagrams illustrating a method of manufacturing the STT-MRAM of FIG. 3.

FIG. 9 is a diagram illustrating a STT-MRAM according to another embodiment of the present invention.

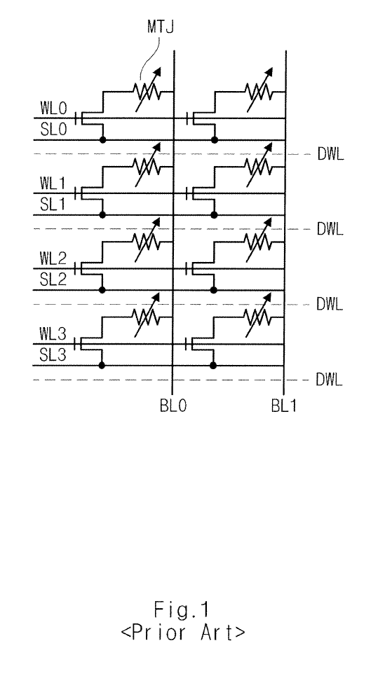

### DESCRIPTION OF EMBODIMENTS

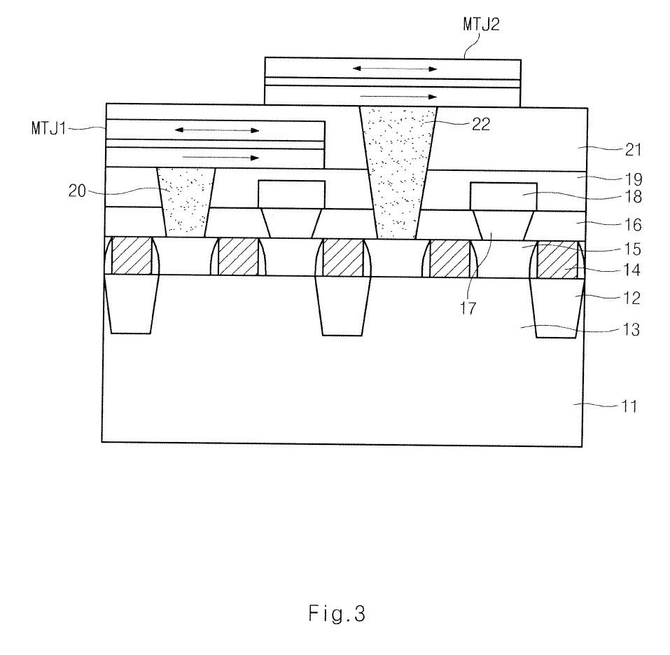

FIG. 3 is a cross-sectional diagram illustrating a STT-MRAM according to an embodiment of the present invention. A gate electrode 14 is formed over a silicon substrate 11 having a device isolation film 12 and an active region 13. A landing plug contact 15 is formed between the gate electrodes 14. A source line contact 17 is formed over the landing plug contact 15 positioned at one side of a source/drain region formed in both sides of the gate electrodes 14. Bottom electrode contacts 20 and 22 are formed over the landing plug contact 15 positioned at the other side of the source/drain region. A source line 18 is formed over the source line contact 17. A MTJ1 and MTJ2 are formed over the bottom electrode contacts 20 and 22, respectively. The source line 18 is formed to be straight in parallel with the gate electrode 14. Each of the MTJ1 and MTJ2 includes two magnetic layers and a tunnel barrier located between the two magnetic layers. The bottom magnetic layer includes a pinned ferromagnetic layer whose magnetization direction is fixed. The top magnetic layer includes a free ferromagnetic layer whose magnetization direction is varied depending on a direction of a current applied to the MTJ.

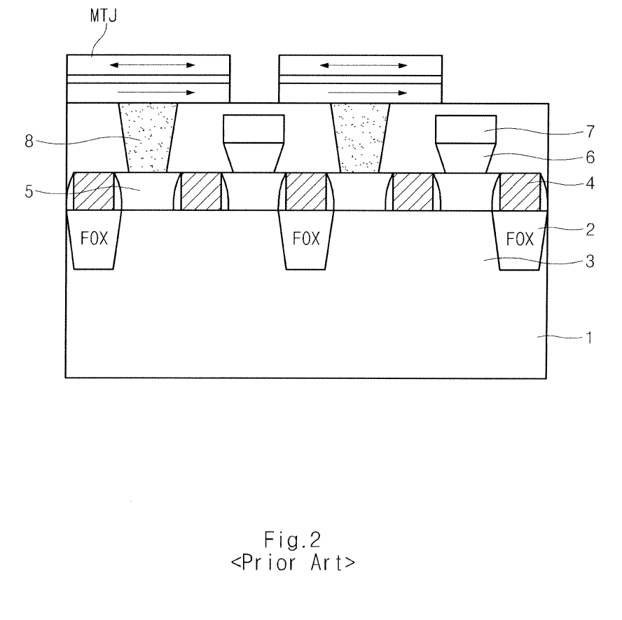

Interlayer insulating films 19 and 21 are formed, respectively, between the source line 18 and the MTJ1, and between the MTJ1 and the MTJ2. That is, the neighboring MTJ1 and MTJ2 are not formed over the same surface and an interlayer insulating film 21 is interposed between the MTJ1 and the MTJ2, respectively, over the different layers. As a result, the free ferromagnetic layers are not adjacent with each other between the neighboring MTJs, thereby inhibiting magnetic interference between the MTJs. The size of the MTJ can be formed to be larger than that of the MTJ of FIG. 2. The ratio of the width and length of the MTJ ranges from 1:1 to 1:5.

A bit line (not shown) connected through a top electrode contact (not shown) is formed over the MTJ1 and MTJ2.

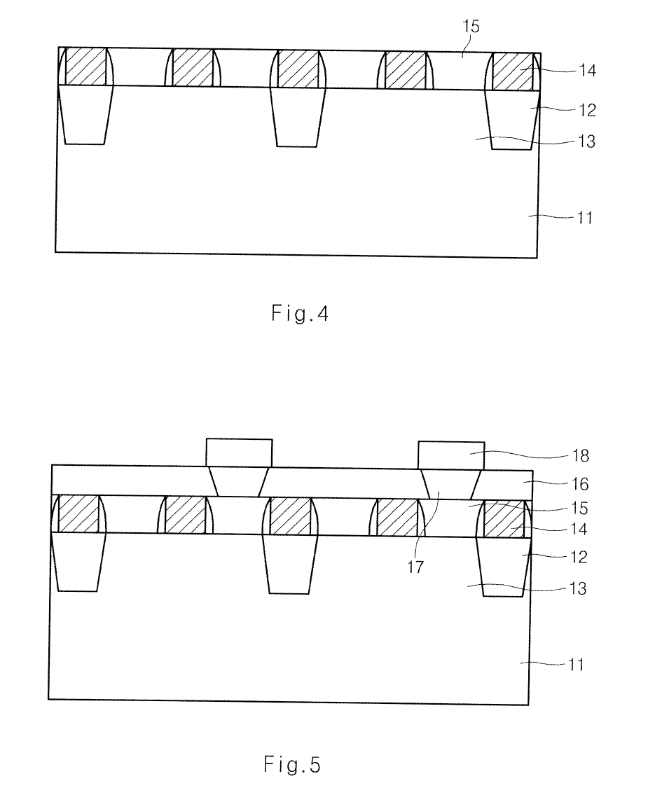

FIGS. 4 to 8 are cross-sectional diagrams illustrating a method of manufacturing the STT-MRAM of FIG. 3.

Referring to FIG. 4, the device isolation film 12 that defines an active region 13 is formed over the silicon substrate 11 by a shallow trench isolation (STI) method. The gate electrode 14 including a word line WL is formed over the device isolation film 12 and the active region 13. The word line WL formed in the device isolation film 12 is a dummy word line DWL. The gate electrode 14 may be formed to have a stacked structure including a gate oxide film (not shown), a polysilicon layer (not shown) and a hard mask layer (not shown).

Impurities are ion-implanted into the silicon substrate of the active region 13 exposed between the gate electrodes 14 to form a source/drain region (not shown).

A landing plug poly is formed over the silicon substrate 11 and the gate electrode 14 to fill a space between the gate electrodes 14. The landing plug poly is planarized to form the landing plug contact 15.

The gate electrode 14, the source/drain region (not shown) and the landing plug contact 15 are formed in the same way of forming them in the conventional DRAM.

Referring to FIG. 5, a first interlayer insulating film 16 is formed over the gate electrode 14 and the landing plug contact 15. The first interlayer insulating film 16 is etched and planarized.

The first interlayer insulating film 16 is selectively etched until the landing plug contact 15 of the source/drain region is exposed, thereby obtaining a source line contact hole (not shown). After a conductive film is formed to fill the source line contact hole, the conductive film is planarized until the first interlayer insulating film 16 is exposed, thereby obtaining a source line contact 17.

A metal layer (not shown) is formed over the first interlayer insulating film 16 including the source line contact 17. The metal layer is patterned with a mask (not shown) that defines a source line 18, thereby obtaining the source line 18 electrically connected to the source line contact 17. The source line 18 is formed to be straight in parallel with a gate.

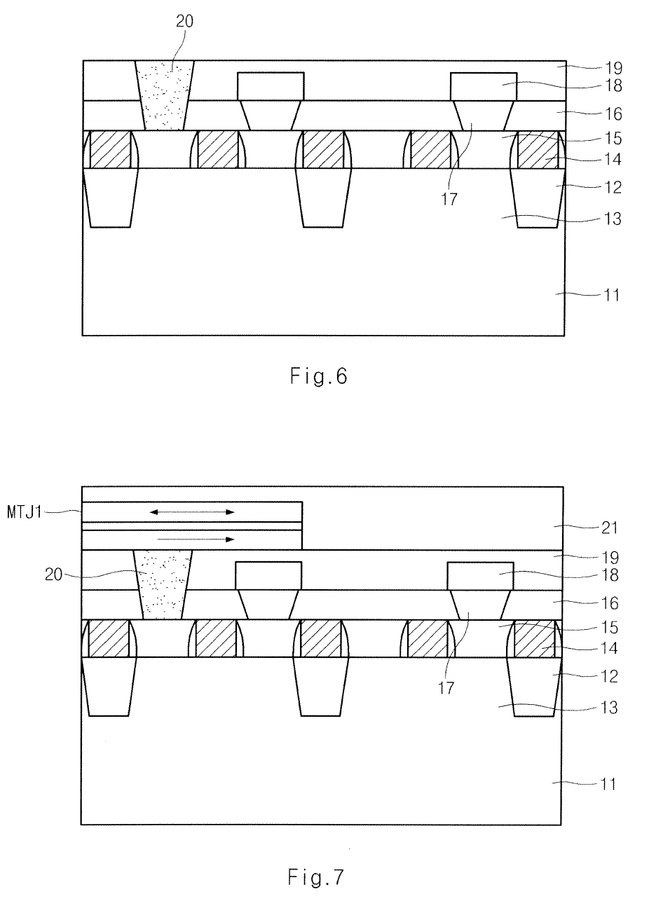

Referring to FIG. 6, a second interlayer insulating film 19 is formed over the source line 18 and the first interlayer insulating film 16. The second interlayer insulating film 19 is etched and planarized. The second interlayer insulating film 19 and the first interlayer insulating film 16 are sequentially selectively etched to expose the landing plug contact 15 of the source/drain region where the source line contact 17 is not formed, thereby obtaining a first bottom electrode contact hole (not shown). The first bottom electrode contact hole is not formed in all cells, but formed in the even or odd gate line.

After a conductive film is formed to fill the first bottom electrode contact hole, the conductive film is etched until the second interlayer insulating film 19 is exposed, thereby obtaining a first bottom electrode contact 20.

Referring to FIG. 7, a pinned ferromagnetic layer whose magnetization direction is fixed, a tunnel burrier, and a free ferromagnetic layer whose magnetization direction is varied depending on a direction of a current are sequentially formed over the first bottom electrode contact 20 and the second interlayer insulating film 19, and they are patterned to form a MTJ1 connected to the first bottom electrode contact 20.

The ratio of the width and length of the MTJ1 ranges from 1:1 to 1:5 so that the MTJ1 may have a desired spin direction. For example, the MTJ1 is formed to have the length of IF in a word line direction and the length of 1˜5 F in a bit line direction, and vice versa. The MTJ1 may be formed to have a square or rectangular shape, or have a circular or oval shape. When the MTJ1 is formed to have an oval shape, the ratio of the major axis and minor axis ranges from 1:1 to 1:5.

After the MTJ1 is formed, a third interlayer insulating film 21 is formed over the second interlayer insulating film 19. The third interlayer insulating film 21 is etched and planarized.

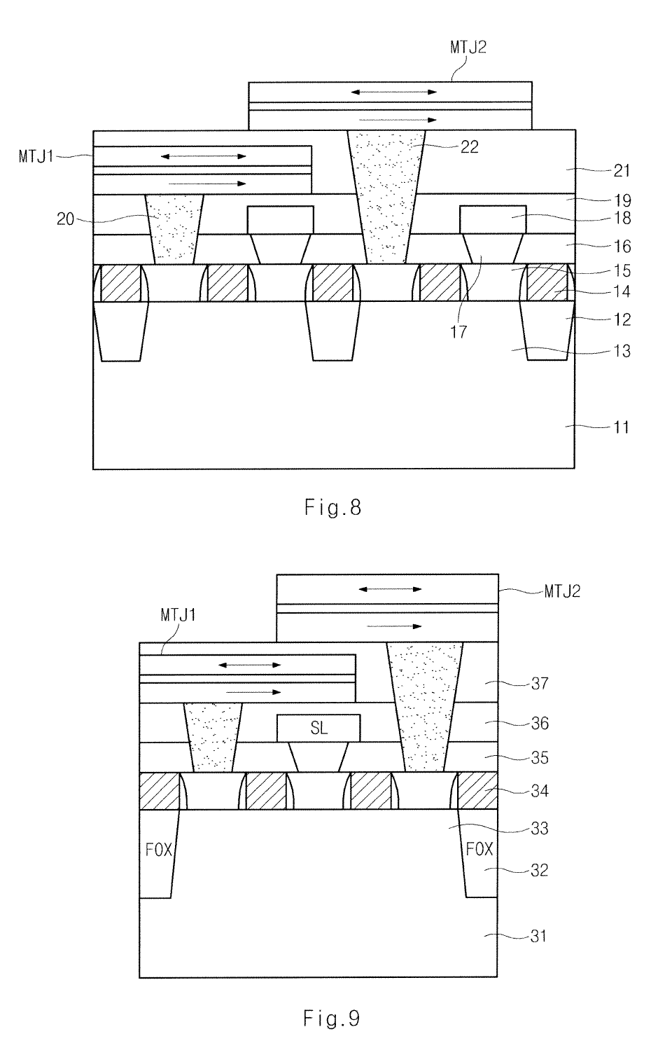

Referring to FIG. 8, the third interlayer insulating film 21, the second interlayer insulating film 19 and the first interlayer insulating film 16 are sequentially etched to expose the landing plug contact 15 of the source/drain region where the source line contact 17 is not formed, thereby obtaining a second bottom electrode contact hole (not shown). The second bottom electrode contact hole is formed to be alternate with the first bottom electrode contact hole. For example, when the first bottom electrode contact hole is formed to be connected with the landing plug contact of the even gate line, the second bottom electrode contact hole is formed to be connected with the landing plug contact of the odd gate line.

After a conductive film is formed to fill the second bottom electrode contact hole, the conductive film is etched until the third interlayer insulating film 21 is exposed, thereby obtaining a second bottom electrode contact 22. The first bottom electrode contact 20 and the second bottom electrode contact 22 may include one selected from the group consisting of W, Ru, Ta and Cu.

A pinned ferromagnetic layer, a tunnel barrier and a free ferromagnetic layer are sequentially formed over the second bottom electrode contact 22 and the third interlayer insulating film 21, and they are patterned to obtain the MTJ2 connected to the second bottom electrode contact 22.

Like the MTJ1, the MTJ2 is formed to have the ratio of the width and length ranging from 1:1 to 1:5, and to have a rectangular shape or an oval shape.

A fourth interlayer insulating film (not shown) is formed over the MTJ2 and the third interlayer insulating film 21. The fourth interlayer insulating film is etched and planarized. The fourth interlayer insulating film and the third interlayer insulating film 21 are selectively etched until the free ferromagnetic layers of the MTJ1 and the MTJ2 are exposed, thereby obtaining a top electrode contact hole (not shown). A conductive layer (not shown) is formed to fill the top electrode contact hole. The conductive layer is etched until the fourth interlayer insulating film is exposed, thereby obtaining a top electrode contact (not shown). A bit line (not shown) is formed over the top electrode contact.

As mentioned above, the MTJs of neighboring STT-MRAM cells are not formed over the same layer but respectively over the different layers to prevent interference between the MTJs. With the same integration of the STT-MRAM, the size of the MTJs can be increased to secure thermal stability.

Although one active region per cell formed in the transistor is exemplified in the embodiment, the present invention is not limited to one active region per cell.

FIG. 9 is a cross-sectional diagram illustrating a STT-MRAM according to another embodiment of the present invention.

In comparison with the STT-MRAM of FIG. 3, the STT-MRAM of FIG. 9 includes two cells formed in one active region, so that two gate electrodes share one source line.

That is, a common source electrode SL of FIG. 9 is connected to a source/drain region shared by the two neighboring gate electrodes. The MTJs (MTJ1, MTJ2) are connected one by one to the source/drain region which is not shared by the two neighboring gate electrodes. The MTJs (MTJ1, MTJ2) are formed, respectively, over the different layers, as shown in FIG. 3.

The gate electrodes formed over the silicon substrate having an isolation film that defines the active region in FIG. 9 can be formed in the same way of forming gate electrodes of the conventional DRAM. The interlayer insulating film formed between a gate and the source electrode SL, between the source electrode SL and the MTJ1, and the between the MTJ1 and the MTJ2 and the source electrode contact and the bottom electrode contact in FIG. 9 can also be formed in the same way shown in FIGS. 4 to 8.

As described above, in the STT-MRAM according to an embodiment of the present invention, the MTJs of the neighboring cells are not formed over the same layer, but respectively over the different layers, thereby preventing interference between the neighboring MTJs. Moreover, the MTJ can be formed to be larger, thereby securing thermal stability.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A multi-stacked spin transfer torque magnetic random access memory (STT-MRAM) device comprising:
a first magnetic tunneling junction (MTJ) connected to a first source/drain region of a first cell; and
a second MTJ connected to a first source/drain region of a second cell adjacent to the first cell,
wherein the first MTJ and the second MTJ are formed in different layers, respectively.

2. The multi-stacked STT-MRAM device according to claim 1, further comprising:
a first source line connected to a second source/drain region of the first cell; and
a second source line connected to a second source/drain region of the second cell.

3. The multi-stacked STT-MRAM device according to claim 2, wherein the first source line and the second source line are formed in the same layer.

4. The multi-stacked STT-MRAM device according to claim 1, wherein the first cell and the second cell are formed in different active regions, respectively.

5. The multi-stacked STT-MRAM device according to claim 1, further comprising a common source line connected to a third source/drain region shared by the first cell and the second cell.

6. The multi-stacked STT-MRAM device according to claim 1, wherein each of the first MTJ and the second MTJ is formed to have a square or rectangular shape.

7. The multi-stacked STT-MRAM device according to claim 6, wherein each of the first MTJ and the second MTJ, respectively, has an ratio of the width and length of 1:1˜1:5.

8. The multi-stacked STT-MRAM device according to claim 1, wherein each of the first MTJ and the second MTJ is formed to have a circular or oval shape.

9. The multi-stacked STT-MRAM device according to claim 8, wherein each of the first MTJ and the second MTJ, respectively, has an ratio of the major axis and minor axis of 1:1˜1:5.

10. A method of manufacturing a multi-stacked spin transfer torque magnetic random access memory (STT-MRAM) device, the method comprising:
forming a first gate electrode and a second gate electrode over a semiconductor substrate;
forming a first source line connected to a first source/drain region adjacent to the first gate electrode and a second source line connected to a second source/drain region adjacent to the second gate electrode over the first and second gate electrodes;
forming a first magnetic tunneling junction (MTJ) connected to a third source/drain region adjacent to the first gate electrode over the first and second source lines; and
forming a second MTJ connected to a fourth source/drain region adjacent to the second gate electrode over the first MTJ.

11. The method according to claim 10, wherein the forming first and second source lines includes:
forming a first interlayer insulating film over the first and second gate electrodes;
selectively etching the first interlayer insulating film to form first and second source line contacts, respectively, connected to the first source/drain region and the second source/drain region; and
forming and patterning a metal film over the first interlayer insulating film, the first source line contact and the second source line contact.

12. The method according to claim 11, wherein the forming a first MTJ includes:
forming a second interlayer insulating film over the first source line, the second source line and the first interlayer insulating film;
selectively etching the second interlayer insulating film and the first interlayer insulating film to form a first bottom electrode contact connected to the third source/drain region;
sequentially forming a first pinned ferromagnetic layer, a first tunnel junction layer and a first free ferromagnetic layer over the second interlayer insulating film and the first bottom electrode contact; and
patterning the first pinned ferromagnetic layer, the first tunnel junction layer and the first free ferromagnetic layer.

13. The method according to claim 12, wherein the forming a second MTJ includes:
forming a third interlayer insulating film over the first MTJ and the second interlayer insulating film;
selectively etching the third interlayer insulating film, the second interlayer insulating film and the first interlayer insulating film to form a second bottom electrode contact connected to the source source/drain region;
sequentially forming a second pinned ferromagnetic layer, a second tunnel junction layer and a second free ferromagnetic layer over the third interlayer insulating film and the second bottom electrode contact; and
patterning the second pinned ferromagnetic layer, the second tunnel junction layer and the second free ferromagnetic layer.

14. A method of manufacturing a multi-stacked spin transfer torque magnetic random access memory (STT-MRAM) device, the method comprising:
forming a first gate electrode and a second gate electrode over a semiconductor substrate;
forming a common source line connected to a first source/drain region adjacent in common to the first and second gate electrodes over the first and second gate electrodes;
forming a first magnetic tunneling junction (MTJ) connected to a second source/drain region adjacent to the first gate electrode over the common source line; and
forming a second MTJ connected to a third source/drain region adjacent to the second gate electrode over the first MTJ.

15. The method according to claim 14, wherein the forming a common source line includes:
forming a first interlayer insulating film over the first gate electrode and the second gate electrode;
selectively etching the first interlayer insulating film to form a source line contact connected to the first source/drain region; and
forming and patterning a metal film over the first interlayer insulating film and the source line contact.

16. The method according to claim 15, wherein the forming a first MTJ includes:
forming a second interlayer insulating film over the common source line and the first interlayer insulating film;
selectively etching the second interlayer insulating film and the first interlayer insulating film to form a first bottom electrode contact connected to the second source/drain region;
sequentially forming a first pinned ferromagnetic layer, a first tunnel junction layer and a first free ferromagnetic layer over the second interlayer insulating film and the first bottom electrode contact; and
patterning the first pinned ferromagnetic layer, the first tunnel junction layer and the first free ferromagnetic layer.

17. The method according to claim 16, wherein the forming a second MTJ includes:
forming a third interlayer insulating film over the first MTJ and the second interlayer insulating film;
selectively etching the third interlayer insulating film, the second interlayer insulating film and the first interlayer insulating film to form a second bottom electrode contact connected to the third source/drain region;
sequentially forming a second pinned ferromagnetic layer, a second tunnel junction layer and a second free ferromagnetic layer over the third interlayer insulating film and the second bottom electrode contact; and
patterning the second pinned ferromagnetic layer, the second tunnel junction layer and the second free ferromagnetic layer.
